(19) United States
(12) Patent Application Publication
(10) Pub. No.: US 2025/0006805 A1
(43) Pub. Date: Jan. 2, 2025

(54) THIN FILM TRANSISTOR UNIT AND MANUFACTURING METHOD THEREFOR, AND SHIFT REGISTER UNIT

(71) Applicants: Chongqing BOE Optoelectronics Technology Co., Ltd., Chongqing (CN); BOE Technology Group Co., Ltd., Beijing (CN)

(72) Inventors: Yan LIU, Beijing (CN); Xiaoyuan WANG, Beijing (CN); Hui GUO, Beijing (CN); Chen XU, Beijing (CN); Guodong YANG, Beijing (CN); Bin WAN, Beijing (CN); Junming CHEN, Beijing (CN); Zhongshan WU, Beijing (CN); Xun PU, Beijing (CN)

(73) Assignees: Chongqing BOE Optoelectronics Technology Co., Ltd., Chongqing (CN); BOE Technology Group Co., Ltd., Beijing (CN)

(21) Appl. No.: 18/278,629

(22) PCT Filed: Aug. 29, 2022
(86) PCT No.: PCT/CN2022/115464

§ 371 Date: Aug. 24, 2023

(51) Int. Cl. H01L 29/417; G09G 3/20; G11C 19/28; H01L 29/66

(52) U.S. Cl. CPC H01L 29/41733; G09G 3/2092; G11C 19/28; H01L 29/66742; G09G 2310/0267; G09G 2310/0286; G09G 2310/08

(57) ABSTRACT

Provided is a thin film transistor unit. The thin film transistor unit includes a first gate, a first gate insulating layer, a first semiconductor layer and a first source/drain electrode layer that are sequentially arranged on a substrate, wherein the first source/drain electrode layer includes a first source and a first drain that are spaced apart from each other along a first direction; and a floating electrode disposed on a side of the first semiconductor layer away from the first gate insulating layer, wherein in the first direction, an orthographic projection of the floating electrode on the substrate falls between an orthographic projection of the first source on the substrate and an orthographic projection of the first drain on the substrate.

### CROSS-REFERENCE TO RELATED APPLICATIONS

This application is a U.S. national stage of international application No. PCT/CN2022/115464, filed on Aug. 29, 2022, the disclosure of which is incorporated herein by reference in its entirety.

### TECHNICAL FIELD

The present disclosure relates to the field of display technologies, and in particular, to a thin film transistor (TFT) unit and a manufacturing method therefor, and a shift register unit.

### BACKGROUND OF THE INVENTION

TFTs are arranged on a substrate of a display apparatus for driving pixels.

### SUMMARY OF THE INVENTION

The present disclosure provides a TFT unit and a manufacturing method therefor, and a shift register unit. The technical solutions are as follows.

In some embodiments, a TFT unit is provided. The TFT unit includes:
a first gate, a first gate insulating layer, a first semiconductor layer and a first source/drain electrode layer that are sequentially arranged on a substrate, wherein the first source/drain electrode layer includes a first source and a first drain that are spaced apart from each other along a first direction; and
a floating electrode disposed on a side of the first semiconductor layer away from the first gate insulating layer, wherein in the first direction, an orthographic projection of the floating electrode on the substrate falls between an orthographic projection of the first source on the substrate and an orthographic projection of the first drain on the substrate;
wherein the orthographic projection of the floating electrode on the substrate is at least partially overlapped with an orthographic projection of the first semiconductor layer on the substrate; the orthographic projection of the floating electrode on the substrate, the orthographic projection of the first source on the substrate and the orthographic projection of the first drain on the substrate each are at least partially overlapped with an orthographic projection of the first gate on the substrate; any two of the floating electrode, the first source and the first drain are at least partially overlapped in a second direction, and the second direction is perpendicular to the first direction.

In some embodiments, the floating electrode, the first source, and the first drain are disposed on a same layer.

In some embodiments, a material of the floating electrode includes metal.

In some embodiments, a length of the floating electrode in the first direction, a length of the first source in the first direction and a length of the first drain in the first direction are equal.

In some embodiments, the first source, the floating electrode and the first drain are equally spaced apart from each other in the first direction.

In some embodiments, a method for manufacturing a TFT unit is provided. The method includes:
sequentially forming a first gate, a first gate insulating layer, a first semiconductor layer and a first source/drain electrode layer on a substrate, wherein the first source/drain electrode layer includes a first source and a first drain that are spaced apart from each other along a first direction; and
forming a floating electrode on a side of the first semiconductor layer away from the substrate, wherein in the first direction, an orthographic projection of the floating electrode on the substrate falls between an orthographic projection of the first source on the substrate and an orthographic projection of the first drain on the substrate;
wherein the orthographic projection of the floating electrode on the substrate is at least partially overlapped with an orthographic projection of the first semiconductor layer on the substrate; the orthographic projection of the floating electrode on the substrate, the orthographic projection of the first source on the substrate and the orthographic projection of the first drain on the substrate each are at least partially overlapped with an orthographic projection of the first gate on the substrate; any two of the floating electrode, the first source and the first drain are at least partially overlapped in a second direction, and the second direction is perpendicular to the first direction.

In some embodiments, forming the first source/drain electrode layer and the floating electrode includes:
forming a source/drain electrode film on the side of the first semiconductor layer away from the substrate; and
patterning the source/drain electrode film to obtain the first source, the first drain and the floating electrode.

In some embodiments, a shift register unit is provided. The shift register unit includes a plurality of thin film transistors (TFTs), each of the TFTs includes at least one TFT unit, and the plurality of TFTs include a plurality of target TFTs. A source or drain of each of the target TFTs is connected to a pull-up node in the shift register unit. At least one of the plurality of target TFTs includes a target TFT unit, and the target TFT unit is of a target structure. The target structure includes:
a first gate, a first gate insulating layer, a first semiconductor layer and a first source/drain electrode layer that are sequentially arranged on a substrate, wherein the first source/drain electrode layer includes a first source and a first drain that are spaced apart from each other along a first direction; and
a floating electrode disposed on a side of the first semiconductor layer away from the first gate insulating layer, wherein in the first direction, an orthographic projection of the floating electrode on the substrate falls between an orthographic projection of the first source on the substrate and an orthographic projection of the first drain on the substrate;
wherein the orthographic projection of the floating electrode on the substrate is at least partially overlapped with an orthographic projection of the first semiconductor layer on the substrate; the orthographic projection of the floating electrode on the substrate, the orthographic projection of the first source on the substrate and the orthographic projection of the first drain on the substrate each are at least partially overlapped with an orthographic projection of the first gate on the substrate; any two of the floating electrode, the first source and the first drain are at least partially overlapped in a second direction, and the second direction is perpendicular to the first direction.

In some embodiments, each of the plurality of target TFT includes the target TFT unit.

In some embodiments, the shift register unit includes an input circuit, a first reset circuit, an output circuit, a second reset circuit, a first pull control circuit, a first pull circuit, a second pull control circuit, a second pull circuit, and a storage capacitor; wherein
the input circuit includes a first transistor, wherein a gate and a first electrode of the first transistor are connected to a signal input terminal, and a second electrode of the first transistor is connected to the pull-up node;
the first reset circuit includes a second transistor and a third transistor, wherein a gate of the second transistor is connected to a first reset signal terminal, a first electrode of the second transistor is connected to the pull-up node, and a second electrode of the second transistor is connected to a first fixed voltage terminal; and a gate of the third transistor is connected to the first reset signal terminal, a first electrode of the third transistor is connected to a first output terminal, and a second electrode of the third transistor is connected to a second fixed voltage terminal;
the output circuit includes a first output transistor and a second output transistor, wherein a gate of the first output transistor is connected to the pull-up node, a first electrode of the first output transistor is connected to a clock signal terminal, and a second electrode of the first output transistor is connected to the first output terminal; and a gate of the second output transistor is connected to the pull-up node, a first electrode of the second output transistor is connected to the clock signal terminal, and a second electrode of the second output transistor is connected to a second output terminal;
the second reset circuit includes a fourth transistor, wherein a gate of the fourth transistor is connected to a second reset signal terminal, a first electrode of the fourth transistor is connected to the pull-up node, and a second electrode of the fourth transistor is connected to the first fixed voltage terminal;
the first pull control circuit includes a fifth transistor, a sixth transistor and a seventh transistor, wherein a gate and a first electrode of the fifth transistor are connected to a first control terminal, and a second electrode of the fifth transistor is connected to a first pull-down node; a gate of the sixth transistor is connected to the pull-up node, a first electrode of the sixth transistor is connected to the first pull-down node, and a second electrode of the sixth transistor is connected to the first fixed voltage terminal; and a gate of the seventh transistor is connected to the signal input terminal, a first electrode of the seventh transistor is connected to the first pull-down node, and a second electrode of the seventh transistor is connected to the first fixed voltage terminal;
the first pull circuit includes an eighth transistor, a ninth transistor and a tenth transistor, wherein a gate of the eighth transistor is connected to the first pull-down node, a first electrode of the eighth transistor is connected to the pull-up node, and a second electrode of the eighth transistor is connected to the first fixed voltage terminal; a gate of the ninth transistor is connected to the first pull-down node, a first electrode of the ninth transistor is connected to the second output terminal, and a second electrode of the ninth transistor is connected to the first fixed voltage terminal; and a gate of the tenth transistor is connected to the first pull-down node, a first electrode of the tenth transistor is connected to the first output terminal, and a second electrode of the tenth transistor is connected to the second fixed voltage terminal;
the second pull control circuit includes an eleventh transistor, a twelfth transistor and a thirteenth transistor, wherein a gate and a first electrode of the eleventh transistor are connected to a second control terminal, and a second electrode of the eleventh transistor is connected to a second pull-down node; a gate of the twelfth transistor is connected to the pull-up node, a first electrode of the twelfth transistor is connected to the second pull-down node, and a second electrode of the twelfth transistor is connected to the first fixed voltage terminal; and a gate of the thirteenth transistor is connected to the signal input terminal, a first electrode of the thirteenth transistor is connected to the second pull-down node, and a second electrode of the thirteenth transistor is connected to the first fixed voltage terminal;
the second pull circuit includes a fourteenth transistor, a fifteenth transistor and a sixteenth transistor, wherein a gate of the fourteenth transistor is connected to the second pull-down node, a first electrode of the fourteenth transistor is connected to the pull-up node, and a second electrode of the fourteenth transistor is connected to the first fixed voltage terminal; a gate of the fifteenth transistor is connected to the second pull-down node, a first electrode of the fifteenth transistor is connected to the second output terminal, and a second electrode of the fifteenth transistor is connected to the first fixed voltage terminal; and a gate of the sixteenth transistor is connected to the second pull-down node, a first electrode of the sixteenth transistor is connected to the first output terminal, and a second electrode of the sixteenth transistor is connected to the second fixed voltage terminal;
a first electrode of the storage capacitor is connected to the pull-up node, and a second electrode of the storage capacitor is connected to the first output terminal;
wherein one of the first electrode and second electrode of each transistor is the source and the other one is the drain.

In some embodiments, at least one of the first transistor, the second transistor, the fourth transistor, the eighth transistor and the fourteenth transistor includes the target TFT unit.

In some embodiments, each of the second transistor, the eighth transistor and the fourteenth transistor includes the target TFT unit.

In some embodiments, both first transistor and the fourth transistor include the target TFT unit.

In some embodiments, except the target TFT units, other TFT units in the plurality of TFTs each include a second gate, a second gate insulating layer, a second semiconductor layer and a second source/drain electrode layer that are sequentially arranged on the substrate, the second source/drain electrode layer includes a second source and a second drain that are spaced apart from each other, and the other TFT units do not include the floating electrode.

In some embodiments, a length of a channel of the target TFT unit is twice a length of each of channels of the other TFT units; and

the channel of the target TFT unit is a part of the first semiconductor layer which is overlapped with the first gate and is not overlapped with the floating electrode, the first source and the first drain, the channel of each of the other TFT units are a part of the second semiconductor layer which is overlapped with the second gate and is not overlapped with the second source and the second drain, and the length direction of the channel is parallel to an arrangement direction of the second source and the second drain of the transistor.

In some embodiments, each of the TFTs is an N-type transistor.

In some embodiments, at least one of the plurality of TFTs includes a source/drain electrode branch and a floating electrode branch, wherein the source/drain electrode branch constitutes a source and a drain of each TFT unit in the TFT, and the floating electrode branch constitutes a floating electrode of each TFT unit in the TFT; and
a first number of the source/drain electrode branches in the TFT is greater than a second number of the floating electrode branches in the TFT, and a difference between the first number and the second number is greater than or equal to 1.

In some embodiments, a gate drive circuit is provided. The gate drive circuit includes:
at least two cascaded shift register units as described in the above embodiments.

In some embodiments, a display panel is provided. The display panel includes a substrate and the gate drive circuit as described in the above embodiments, wherein the gate drive circuit is disposed on the substrate.

In some embodiments, a display apparatus is provided. The display apparatus includes a power supply assembly and the display panel as described in the above embodiments, wherein the power supply assembly is configured to supply power to the display panel.

### BRIEF DESCRIPTION OF DRAWINGS

To describe the technical solutions in the embodiments of the present disclosure more clearly, the drawings required for describing the embodiments are briefly described below. The drawings in the following description show merely some embodiments of the present disclosure, and those of ordinary skill in the art may still derive other drawings from these drawings without creative effort.

FIG. 1 is a schematic structural diagram of a TFT unit in the related art;

FIG. 2 is a schematic structural diagram of a TFT unit according to some embodiments of the present disclosure;

FIG. 3 is a top view of a TFT unit according to some embodiments of the present disclosure;

FIG. 4 is a flowchart of a method for manufacturing a TFT unit according to some embodiments of the present disclosure;

FIG. 5 is a partial schematic diagram of a shift register unit according to some embodiments of the present disclosure;

FIG. 6 is a circuit diagram of a shift register unit according to some embodiments of the present disclosure;

FIG. 7 is a timing diagram of a driving process of a shift register unit according to some embodiments of the present disclosure;

FIG. 8 is a schematic structural diagram of a TFT unit other than a target TFT unit in a plurality of TFT units in a shift register according to some embodiments of the present disclosure;

FIG. 9 is a schematic diagram of a characteristic test result of a TFT unit according to some embodiments of the present disclosure;

FIG. 10 is a partial schematic structural diagram of the shift register unit in FIG. 5;

FIG. 11 is a cross-sectional view of FIG. 10 along a direction AA;

FIG. 12 is a partial schematic diagram of another shift register unit according to some embodiments of the present disclosure;

FIG. 13 is a schematic structural diagram of a gate drive circuit according to some embodiments of the present disclosure;

FIG. 14 is a schematic structural diagram of a display panel according to some embodiments of the present disclosure; and

FIG. 15 is a schematic structural diagram of a display apparatus according to some embodiments of the present disclosure.

### DETAILED DESCRIPTION OF THE INVENTION

To make the objective, technical solutions, and advantages of the present disclosure clearer, the embodiments of the present disclosure are described in further detail below with reference to the drawings.

In the related art, a TFT generally includes a gate, a gate insulating layer, a semiconductor layer and a source/drain electrode layer that are sequentially arranged on a substrate, and the source/drain electrode layer includes a source and a drain which are connected to the semiconductor layer and spaced apart from each other. A part, overlapped with the gate, of the semiconductor layer is the channel of the TFT. The drive ability of the TFT is positively correlated with the width/length ratio of its channel. At present, in order to increase the drive ability of the TFT, the channel length is usually set to be small.

However, in the case that the channel length of the TFT is set to be too small, an excessive number of electrons are accumulated in the channel, which causes the TFT to heat or even burn, resulting in a poor display effect of the display apparatus.

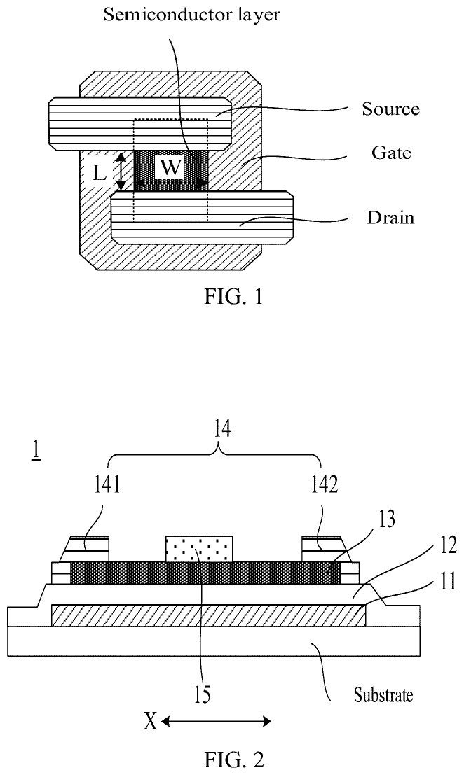

FIG. 1 is a schematic structural diagram of a TFT unit in the related art. Referring to FIG. 1, in the gate driven on array (GOA) circuit (also referred to as a gate drive circuit) in the prior art, the channel of the conventional TFT unit is narrow (that is, the channel length L is small). For example, the channel length is 3.6 μm, 4 μm, 5 μm, or the like, such that electrons in the source region of the TFT unit can be quickly transported to the drain region, and the working efficiency of the shift register unit 01 can be improved. The channel of the TFT unit is a part, overlapped with the gate but not overlapped with the source and the drain, of the semiconductor layer of the TFT unit.

However, due to the narrow channel of the TFT unit, when a large current flows through the TFT unit, according to a formula (1):

$$Idx = \frac{W}{L} μ Ci ( Vgs - Vth ) Vds ,$$

it can be known that a large current Ids is generated between the source and the drain as the voltage difference Vds between the source and the drain increases, and the Joule heat caused by the large current Ids easily causes the source and the drain of the TFT unit to thermally breakdown, resulting in burnout of the TFT unit. In addition, when the channel length L of the TFT unit is small, the electric field per unit length of the TFT unit is relatively large, and high-energy electrons enter the insulating layer and are trapped, which leads to accumulation of charges on the surface of the insulating layer (that is, too many electrons accumulate in the TFT unit), resulting in heating of the TFT unit and even channel burnout, which further leads to the failure of the GOA circuit and the abnormal display of the display apparatus. Moreover, the charge accumulation intensifies over time, which leads to an increase in the threshold voltage Vth, affecting the control of the gate voltage on the channel current and reducing the device performance. In the formula (1), W represents the width of the channel of the TFT unit, L represents the length of the channel of the TFT unit, μ represents the electron mobility, Ci represents the capacitance, Vgs represents the voltage difference between the gate and the source, Vth represents the threshold voltage, and Vds represents the current between the source and the drain.

FIG. 2 is a schematic structural diagram of a TFT unit according to some embodiments of the present disclosure. Referring to FIG. 2, the TFT unit 1 includes a first gate 11, a first gate insulating layer 12, a first semiconductor layer 13 and a first source/drain electrode layer 14 that are sequentially arranged on a substrate. The first source/drain electrode layer 14 includes a first source 141 and a first drain 142 that are spaced apart from each other along a first direction X. Referring to FIG. 2, the TFT unit 1 further includes a floating electrode 15 disposed on the side of the first semiconductor layer 13 away from the first gate insulating layer 12. An orthographic projection of the floating electrode 15 on the substrate falls between an orthographic projection of the first source 141 on the substrate and an orthographic projection of the first drain 142 on the substrate. For example, in FIG. 2, the floating electrode 15 is spaced from the first source 141 and from the first drain 142.

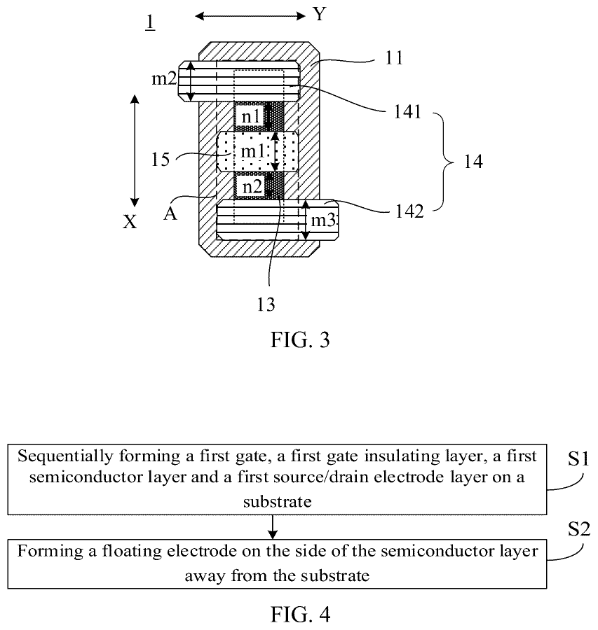

FIG. 3 is a top view of a TFT unit according to some embodiments of the present disclosure. Referring to FIG. 2 and FIG. 3, the orthographic projection of the floating electrode 15 on the substrate at least partially overlaps with an orthographic projection of the first semiconductor layer 13 on the substrate. That is, in the TFT unit 1, the part of the first semiconductor layer 13 which is overlapped with the first source 141, the part of the first semiconductor layer 13 which is overlapped with the first drain 142, and the part of the first semiconductor layer 13 which is overlapped with the floating electrode 15 are integrated.

In addition, the orthographic projection of the floating electrode 15 on the substrate, the orthographic projection of the first source 141 on the substrate and the orthographic projection of the first drain 142 on the substrate are each at least partially overlapped with the orthographic projection of the first gate 11 on the substrate. That is, in the TFT unit 1, the part of the first gate 11 which is overlapped with the first source 141, the part of the first gate 11 which is overlapped with the first drain 142, and the part of the first gate 11 which is overlapped with the floating electrode 15 are integrated.

Any two of the floating electrode 15, the first source 141 and the first drain 142 are at least partially overlapped in a second direction Y. The second direction Y is perpendicular to the first direction X. That is, the floating electrode 15 is at least partially overlapped with the first source 141 in the second direction Y, the floating electrode 15 is at least partially overlapped with the first drain 142 in the second direction Y, and the first source 141 is at least partially overlapped with the first drain 142 in the second direction Y. The overlapping part between the floating electrode 15, the first source 141 and the first drain 142 in the second direction Y is shown in the region A in FIG. 3.

It should be noted that if the floating electrode 15, the first source 141 and the first drain 142 are disposed in the same layer, any two of the orthographic projection of the floating electrode 15 on a reference plane, the orthographic projection of the first source 141 on the reference plane and the orthographic projection of the first drain 142 on the reference plane are at least partially overlapped. The reference plane is perpendicular to the bearing surface of the substrate and parallel to the second direction Y. If the floating electrode 15, the first source 141 and the first drain 142 are not disposed in the same layer, two of the orthographic projection of the floating electrode 15 on the reference plane, the orthographic projection of the first source 141 on the reference plane and the orthographic projection of the first drain 142 on the reference plane are not overlapped. However, no matter whether the floating electrode 15, the first source 141 and the first drain 142 are disposed in the same layer, the following condition is satisfied: any two of the floating electrode 15, the first source 141 and the first drain 142 are at least partially overlapped in the second direction Y.

In the embodiments of the present disclosure, the TFT unit 1 includes the floating electrode 15, and the floating electrode 15 has a function of dissipating heat for the TFT unit 1 to some extent, which can prevent irreversible damage to the first semiconductor layer 13 (for example, the first semiconductor layer 13 is rendered conductive) caused by the high temperature of the TFT unit 1. Moreover, since the floating electrode 15 is disposed between the first source 141 and the first drain 142, the floating electrode 15 has a voltage dividing effect on the first source 141 and the first drain 142 of the TFT unit 1, which can prevent excessive electrons from accumulating in the channel caused by large electric field intensity, thereby preventing the TFT unit 1 from heating or even burning. In this way, the stability and reliability of the TFT unit 1 is improved, and the display effect of the display apparatus is improved.

The channel of the TFT unit 1 refers to the part, overlapped with the first gate 11 but not overlapped with the floating electrode 15, the first source 141 and the first drain 142, of the first semiconductor layer 13 in the TFT unit 1.

In summary, the embodiments of the present disclosure provide a TFT unit. The TFT unit includes a first gate, a first gate insulating layer, a first semiconductor layer, and a first source/drain electrode layer and a floating electrode that are disposed on the side of the first semiconductor layer away from the first gate insulating layer. The first source/drain electrode layer includes a first source and a first drain spaced apart from each other. The orthographic projection of the floating electrode on the substrate falls between the orthographic projection of the first source on the substrate and the orthographic projection of the first drain on the substrate. The floating electrode has a function of dissipating heat, which can prevent the first semiconductor layer from being rendered conductive due to high temperature. Moreover, since the floating electrode is disposed between the first source and the first drain, the floating electrode has a voltage dividing effect on the first source and the first drain of the TFT unit, which can prevent excessive electrons from accumulating in the channel caused by large electric field intensity, thereby preventing the TFT unit from heating or even burning. In this way, the stability and reliability of the TFT unit is improved, and the display effect of the display apparatus is improved.

In the embodiments of the present disclosure, the floating electrode 15, the first source 141 and the first drain 142 are manufactured by the same patterning process. For example, the floating electrode 15, the first source 141 and the first drain 142 are made of the same material by the same patterning process. The material of the floating electrode 15, the first source 141 and the first drain 142 includes metal, such as copper (Cu).

In the embodiments of the present disclosure, the floating electrode 15 is added between the first source 141 and the first drain 142 of the TFT unit 1, and the material of the floating electrode 15 includes Cu. The higher thermal conductivity of Cu can improve the heat dissipation capacity of the TFT unit 1, and can avoid damage caused by high temperature to the first semiconductor layer 13 of the TFT unit 1.

In some embodiments, the process of manufacturing the floating electrode 15, the first source 141 and the first drain 142 includes: forming a metal material film on the side of the first semiconductor layer 13 away from the substrate; coating the side of the metal material film away from the substrate with photoresist; exposing the metal material film coated with photoresist by using a mask; developing the photoresist with a developing solution; etching, by using an etching solution, the part of the metal material film which is not protected by the photoresist after developing; and removing the photoresist.

Referring to FIG. 3, the length m1 of the floating electrode 15 in the first direction X (that is, the width of the floating electrode 15), the length m2 of the first source 141 in the first direction X (that is, the width of the first source 141) and the length m3 of the first drain 142 in the first direction X (that is, the width of the first drain 142) are equal. Certainly, the length m1 of the floating electrode 15 in the first direction X, the length m2 of the first source 141 in the first direction X and the length m3 of the first drain 142 in the first direction X may not be equal, which is not limited in the embodiments of the present disclosure.

In some embodiments, the width of the floating electrode 15, the width of the first source 141 and the width of the first drain 142 are all greater than or equal to 2.5 μm. The width of the floating electrode 15, the width of the first source 141 and the width of the first drain 142 are related to the following factors: the narrow bezel, the length of the channel and the heat dissipation performance.

For example, if the width of the floating electrode 15, the width of the first source 141 and the width of the first drain 142 are too large, design requirements for the narrow bezel of the product are affected. If the width of the floating electrode 15, the width of the first source 141 and the width of the first drain 142 are too large, the length of the channel is too small, which can lead to the short circuit of the first source 141 and the first drain 142 of the TFT unit, resulting in the loss of the semiconductor function. If the width of the floating electrode 15, the width of the first source 141 and the width of the first drain 142 are too small, the length of the channel is too large, which can lead to small normalized current Ion of the TFT unit, which is not conducive to practical use. The larger the width of the floating electrode 15, the width of the first source 141 and the width of the first drain 142, the better the heat dissipation performance. The smaller the width of the floating electrode 15, the width of the first source 141 and the width of the first drain 142, the worse the heat dissipation performance.

In the embodiments of the present disclosure, the floating electrode 15, the first source 141 and the first drain 142 can be specifically designed in consideration of the above factors.

In some embodiments, the first source 141, the floating electrode 15 and the first drain 142 are equally spaced apart from each other in the first direction X. That is, the distance n1 between the first source 141 and the floating electrode 15 is equal to the distance n2 between the floating electrode 15 and the first drain 142. Certainly, the first source 141, the floating electrode 15 and the first drain 142 may alternatively be unequally spaced apart from each other in the first direction X, which is not limited in the embodiments of the present disclosure.

In summary, the embodiments of the present disclosure provide a TFT unit. The TFT unit includes a first gate, a first gate insulating layer, a first semiconductor layer, and a first source/drain electrode layer and a floating electrode that are disposed on the side of the first semiconductor layer away from the first gate insulating layer. The first source/drain electrode layer includes a first source and a first drain spaced apart from each other. The orthographic projection of the floating electrode on the substrate falls between the orthographic projection of the first source on the substrate and the orthographic projection of the first drain on the substrate. The floating electrode has a function of dissipating heat, which can prevent the first semiconductor layer from being rendered conductive due to high temperature. Moreover, since the floating electrode is disposed between the first source and the first drain, the floating electrode has a voltage dividing effect on the first source and the first drain of the TFT unit, which can prevent excessive electrons from accumulating in the channel caused by large electric field intensity, thereby preventing the TFT unit from heating or even burning. In this way, the stability and reliability of the TFT unit is improved, and the display effect of the display apparatus is improved.

FIG. 4 is a flowchart of a method for manufacturing a TFT unit according to some embodiments of the present disclosure. The method is used to manufacture the TFT unit in the above embodiments. Referring to FIG. 4, the method includes the following steps.

In step S1, a first gate, a first gate insulating layer, a first semiconductor layer and a first source/drain electrode layer are sequentially formed on a substrate.

The first source/drain electrode layer 14 includes a first source 141 and a first drains 142 spaced apart from each other along a first direction X.

In step S2, a floating electrode is formed on the side of the semiconductor layer away from the substrate.

The orthographic projection of the floating electrode 15 on the substrate falls between the orthographic projection of the first source 141 on the substrate and the orthographic projection of the first drain 142 on the substrate.

In some embodiments, the floating electrode 15, the first source 141 and the first drain 142 are manufactured by the same patterning process. For example, the floating electrode 15, the first source 141 and the first drain 142 are made of the same material by the same patterning process. The material of the floating electrode 15, the first source 141 and the first drain 142 includes metal, such as Cu.

In some embodiments, the process of manufacturing the floating electrode 15, the first source 141 and the first drain 142 includes: forming a metal material film (a source/drain film) on the side of the first semiconductor layer 13 away from the substrate; coating the side of the metal material film away from the substrate with photoresist; exposing the metal material film coated with photoresist by using a mask; developing the photoresist with a developing solution; etching, by using an etching solution, the part of the metal material film which is not protected by the photoresist after developing; and removing the photoresist.

In the embodiments of the present disclosure, the orthographic projection of the floating electrode 15 on the substrate falls between the orthographic projection of the first source 141 on the substrate and the orthographic projection of the first drain 142 on the substrate. The orthographic projection of the floating electrode 15 on the substrate is at least partially overlapped with the orthographic projection of the first semiconductor layer 13 on the substrate. That is, in the TFT unit, the part of the first semiconductor layer 13 which is overlapped with the first source 141, the part of the first semiconductor layer 13 which is overlapped with the first drain 142, and the part of the first semiconductor layer 13 which is overlapped with the floating electrode 15 are integrated.

In addition, the orthographic projection of the floating electrode 15 on the substrate, the orthographic projection of the first source 141 on the substrate and the orthographic projection of the first drain 142 on the substrate are each at least partially overlapped with the orthographic projection of the first gate 11 on the substrate. That is, in the TFT unit, the part of the first gate 11 which is overlapped with the first source 141, the part of the first gate 11 which is overlapped with the first drain 142, and the part of the first gate 11 which is overlapped with the floating electrode 15 are integrated.

Any two of the floating electrode 15, the first source 141 and the first drain 142 are at least partially overlapped in a second direction Y. The second direction Y is perpendicular to the first direction X. That is, the floating electrode 15 is at least partially overlapped with the first source 141 in the second direction Y, the floating electrode 15 is at least partially overlapped with the first drain 142 in the second direction Y, and the first source 141 is at least partially overlapped with the first drain 142 in the second direction Y.

In the embodiments of the present disclosure, the manufactured TFT unit 1 includes the floating electrode 15, and the floating electrode 15 has a function of dissipating heat for the TFT unit 1 to some extent, which can prevent irreversible damage to the first semiconductor layer 13 (for example, the first semiconductor layer 13 is rendered conductive) caused by the high temperature of the TFT unit 1. Moreover, since the floating electrode 15 is disposed between the first source 141 and the first drain 142, the floating electrode 15 has a voltage dividing effect on the first source 141 and the first drain 142 of the TFT unit 1, which can prevent excessive electrons from accumulating in the channel caused by large electric field intensity, thereby preventing the TFT unit 1 from heating or even burning. In this way, the stability and reliability of the TFT unit 1 is improved, and the display effect of the display apparatus is improved.

In summary, the embodiments of the present disclosure provide a method for manufacturing a TFT unit. The TFT unit manufactured by this method includes a first gate, a first gate insulating layer, a first semiconductor layer, and a first source/drain electrode layer and a floating electrode that are disposed on the side of the first semiconductor layer away from the first gate insulating layer. The first source/drain electrode layer includes a first source and a first drain spaced apart from each other. The orthographic projection of the floating electrode on the substrate falls between the orthographic projection of the first source on the substrate and the orthographic projection of the first drain on the substrate. The floating electrode has a function of dissipating heat, which can prevent the first semiconductor layer from being rendered conductive due to high temperature. Moreover, since the floating electrode is disposed between the first source and the first drain, the floating electrode has a voltage dividing effect on the first source and the first drain of the TFT unit, which can prevent excessive electrons from accumulating in the channel caused by large electric field intensity, thereby preventing the TFT unit from heating or even burning. In this way, the stability and reliability of the TFT unit is improved, and the display effect of the display apparatus is improved.

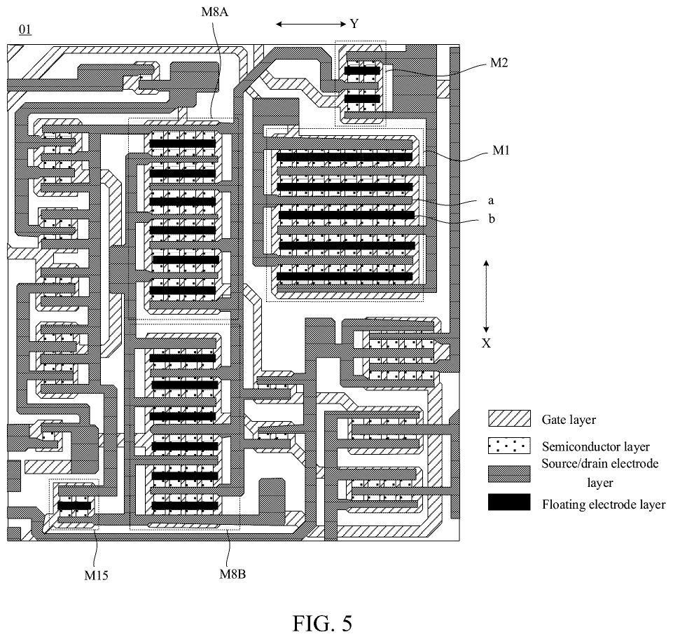

FIG. 5 is a partial schematic diagram of a shift register unit according to some embodiments of the present disclosure. Referring to FIG. 5, the shift register unit 01 includes a plurality of TFTs. Each TFT includes at least one TFT unit. For example, each TFT includes a plurality of TFT units connected in parallel. The plurality of TFTs include a plurality of target TFTs, and a source or drain of each target TFT is connected to a pull-up node PU in the shift register unit 01.

A TFT unit in at least one of the plurality of target TFTs is a target TFT unit, and the target TFT unit is of a target structure. The target structure is the structure of the TFT unit 1 according to the above embodiments. That is, the TFT unit of at least one target TFT in the shift register unit 01 is the TFT unit 1 provided in the above embodiments.

In the embodiments of the present disclosure, the pull-up node PU of the shift register unit 01 has a higher voltage in the output phase because of the bootstrap effect of a storage capacitor C in the shift register unit 01. As a result, a high current easily generates in the TFT unit whose first source 141 or first drain 142 is connected to the pull-up node PU, that is, the TFT unit whose first source 141 or first drain 142 is connected to the pull-up node is more likely to heat or burn than other TFT units.

In at least one target TFT, the TFT unit whose first source 141 or first drain 142 is connected to the pull-up node PU is designed as the TFT unit provided in the above embodiments (that is, the TFT unit 1 including the floating electrode 15), which can improve the heat dissipation capability of the at least one target TFT, thereby avoiding irreversible damage caused by the high temperature of the target TFT to the first semiconductor layer 13 in the TFT unit of the target TFT (for example, the first semiconductor layer 13 is rendered conductive). Moreover, since the floating electrode 15 is disposed between the first source 141 and the first drain 142 in the target TFT unit, the floating electrode 15 has a voltage dividing effect on the first source 141 and the first drain 142 of the target TFT unit, which can prevent excessive electrons from accumulating in the channel caused by large electric field intensity, thereby preventing the target TFT unit from heating or even burning. In this way, the stability and reliability of the target TFT is improved, the reliability of the shift register unit 10 is increased, and the display effect of the display apparatus is improved.

In the embodiments of the present disclosure, the TFT units in the plurality of target TFTs of the shift register unit 01 are all target TFT units, that is, the TFT units in the plurality of target TFTs are all of the target structure. In this way, the stability and reliability of each target TFT can be ensured, thereby further ensuring the reliability of the shift register unit 01.

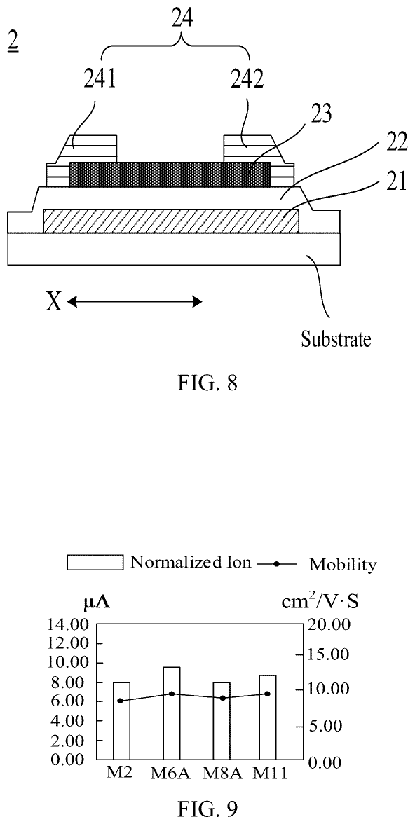

In the shift register unit 01 shown in FIG. 5, the gate layer, the semiconductor layer, the source/drain electrode layer and the floating electrode layer are shown with different filling patterns. The gate layer includes the gate of each TFT unit included in the TFTs of the shift register unit 01 (for example, the gate 11 and the gate 21 which is shown in FIG. 8). The semiconductor layer includes the semiconductor layer of each TFT unit included in the TFTs of the shift register unit 01 (for example, the first semiconductor layer 13 and the second semiconductor layer 23 which is shown in FIG. 8). The source/drain electrode layer includes the source and the drain of each TFT unit included in the TFTs in the shift register unit 01 (for example, the first source 141 and the first drain 142, and a second source 241 and a second drain 242 shown in FIG. 8). The floating electrode layer includes a floating electrode 15 of each TFT unit included in the TFTs of the shift register unit 01. FIG. 5 shows the source/drain electrode layer and the floating electrode layer with different filling patterns, but it does not mean that the source/drain electrode layer and the floating electrode layer are not disposed in the same layer.

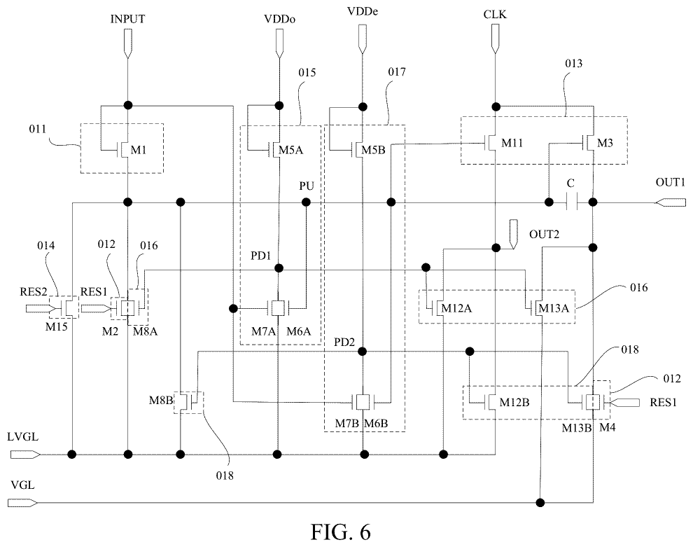

FIG. 6 is a circuit diagram of a shift register unit according to some embodiments of the present disclosure. Referring to FIG. 6, the shift register unit 01 includes an input circuit 011, a first reset circuit 012, an output circuit 013, a second reset circuit 014, a first pull control circuit 015, a first pull circuit 016, a second pull control circuit 017, a second pull circuit 018 and a storage capacitor C.

The input circuit 011 includes a first transistor M1. A gate and a first electrode of the first transistor M1 are connected to a signal input terminal INPUT, and a second electrode of the first transistor M1 is connected to a pull-up node PU.

The first reset circuit 012 includes a second transistor M2 and a third transistor M4. A gate of the second transistor M2 is connected to a first reset signal terminal RES1, a first electrode of the second transistor M2 is connected to the pull-up node PU, and a second electrode of the second transistor M2 is connected to a first fixed voltage terminal LVGL. A gate of the third transistor M4 is connected to the first reset signal terminal RES1, a first electrode of the third transistor M4 is connected to a first output terminal OUT1, and a second electrode of the third transistor M4 is connected to a second fixed voltage terminal VGL.

The output circuit 013 includes a first output transistor M3 and a second output transistor M11. A gate of the first output transistor M3 is connected to the pull-up node PU, a first electrode of the first output transistor M3 is connected to a clock signal terminal CLK, and a second electrode of the first output transistor M3 is connected to the first output terminal OUT1. A gate of the second output transistor M11 is connected to the pull-up node PU, a first electrode of the second output transistor M11 is connected to the clock signal terminal CLK, and a second electrode of the second output transistor M11 is connected to a second output terminal OUT2.

The second reset circuit 014 includes a fourth transistor M15. A gate of the fourth transistor M15 is connected to a second reset signal terminal RES2, a first electrode of the fourth transistor M15 is connected to the pull-up node PU, and a second electrode of the fourth transistor M15 is connected to the first fixed voltage terminal LVGL.

The first pull control circuit 015 includes a fifth transistor M5A, a sixth transistor M6A and a seventh transistor M7A. A gate and a first electrode of the fifth transistor M5A are connected to a first control terminal VDDo, and a second electrode of the fifth transistor M5A is connected to a first pull-down node PD1. A gate of the sixth transistor M6A is connected to the pull-up node PU, a first electrode of the sixth transistor M6A is connected to the first pull-down node PD1, and a second electrode of the sixth transistor M6A is connected to the first fixed voltage terminal LVGL. A gate of the seventh transistor M7A is connected to the signal input terminal INPUT, a first electrode of the seventh transistor M7A is connected to the first pull-down node PD1, and a second electrode of the seventh transistor M7A is connected to the first fixed voltage terminal LVGL.

The first pull circuit 016 includes an eighth transistor M8A, a ninth transistor M12A and a tenth transistor M13A. A gate of the eighth transistor M8A is connected to the first pull-down node PD1, a first electrode of the eighth transistor M8A is connected to the pull-up node PU, and a second electrode of the eighth transistor M8A is connected to the first fixed voltage terminal LVGL. A gate of the ninth transistor M12A is connected to the first pull-down node PD1, a first electrode of the ninth transistor M12A is connected to the second output terminal OUT2, and a second electrode of the ninth transistor M12A is connected to the first fixed voltage terminal LVGL. A gate of the tenth transistor M13A is connected to the first pull-down node PD1, a first electrode of the tenth transistor M13A is connected to the first output terminal OUT1, and a second electrode of the tenth transistor M13A is connected to the second fixed voltage terminal VGL.

The second pull control circuit 017 includes an eleventh transistor M5B, a twelfth transistor M6B and a thirteenth transistor M7B. A gate and a first electrode of the eleventh transistor M5B are connected to a second control terminal VDDe, and a second electrode of the eleventh transistor M5B is connected to the second pull-down node PD2. A gate of the twelfth transistor M6B is connected to the pull-up node PU, a first electrode of the twelfth transistor M6B is connected to the second pull-down node PD2, and a second electrode of the twelfth transistor M6B is connected to the first fixed voltage terminal LVGL. A gate of the thirteenth transistor M7B is connected to the signal input terminal INPUT, a first electrode of the thirteenth transistor M7B is connected to the second pull-down node PD2, and a second electrode of the thirteenth transistor M7B is connected to the first fixed voltage terminal LVGL.

The second pull circuit 018 includes a fourteenth transistor M8B, a fifteenth transistor M12B and a sixteenth transistor M13B. A gate of the fourteenth transistor M8B is connected to the second pull-down node PD2, a first electrode of the fourteenth transistor M8B is connected to the pull-up node PU, and a second electrode of the fourteenth transistor M8B is connected to the first fixed voltage terminal LVGL. A gate of the fifteenth transistor M12B is connected to the second pull-down node PD2, a first electrode of the fifteenth transistor M12B is connected to the second output terminal OUT2, and a second electrode of the fifteenth transistor M12B is connected to the first fixed voltage terminal LVGL. A gate of the sixteenth transistor M13B is connected to the second pull-down node PD2, a first electrode of the sixteenth transistor M13B is connected to the first output terminal OUT1, and a second electrode of the sixteenth transistor M13B is connected to the second fixed voltage terminal VGL.

A first electrode of the storage capacitor C is connected to the pull-up node PU, and a second electrode of the storage capacitor C is connected to the first output terminal OUT1.

One of the first electrode and second electrode of each transistor is the source and the other one is the drain.

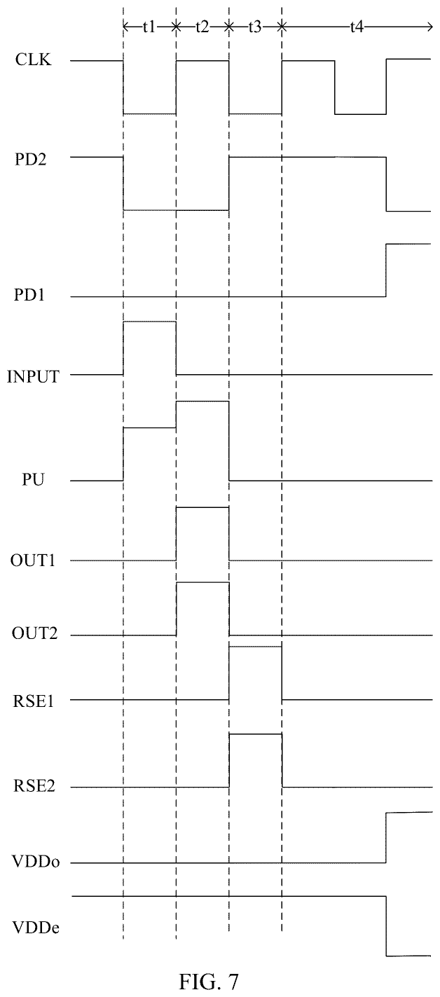

FIG. 7 is a timing diagram of a process of driving a shift register unit according to some embodiments of the present disclosure. The driving method of the shift register unit 01 according to the embodiments of the present disclosure is described in detail by taking the shift register unit 01 shown in FIG. 6 as an example.

Referring to FIG. 6 and FIG. 7, in a charging phase t1, an input signal output from the signal input terminal INPUT is at a first potential, and a first reset signal output from the first reset signal terminal RSE1 and a clock signal output from the clock signal terminal are at a second potential. At this time, the first transistor M1, the seventh transistor MA7 and the thirteenth transistor M7B are turned on, and the signal input terminal INPUT outputs the input signal to one terminal of the storage capacitor C via the first transistor M1. It can be seen from FIG. 7 that the input signal is at the same potential as the second control terminal VDDe, and both are at a high potential VGH, such that the storage capacitor C is charged and the potential at the pull-up node PU is pulled up. In addition, the first fixed voltage terminal LVGL outputs a first fixed voltage signal to the first pull-down node PD1 via the seventh transistor M7A to lower down the potential at the first pull-down node PD1, and outputs a first fixed voltage signal to the second pull-down node PD2 via the thirteenth transistor M7B to lower down the potential at the second pull-down node PD2. Therefore, the ninth transistor M12A, the tenth transistor M13A, the fifteenth transistor M12B and the sixteenth transistor M13B are turned off to avoid affecting the potential at the pull-up node PU. In this case, because the potential at the pull-up node PU is pulled up, the first output transistor M3 and the second output transistor M11 are turned on, and the first fixed voltage terminal LVGL outputs the first fixed voltage signal to the first output terminal OUT1 and the second output terminal OUT2, to lower the potential of the first output terminal OUT1 and the potential of the second output terminal OUT2.

In an output phase t2, the input signal output from the signal input terminal INPUT, the first reset signal output from the first reset signal terminal RSE1 and the second reset signal output from the second reset signal terminal RSE2 are at a second potential, and the second transistor M2, the third transistor M4 and the fourth transistor M15 are turned off. The clock signal output from the clock signal terminal CLK is at the first potential, the pull-up node PU has no discharge path to maintain at the first potential, and the pull-up node PU continues to pull up the potential due to the bootstrap effect of the storage capacitor C (for example, from VGH to twice of VGH). The first output transistor M3 and the second output transistor M11 are fully turned on, the clock signal terminal CLK outputs the clock signal to the first output terminal OUT1 and the second output terminal OUT2, and a first output signal output from the first output terminal OUT1 and a second output signal output from the second output terminal OUT2 are both at the first potential. The first output signal can enable shift transfer between the shift register unit 01 of the current stage and the shift register unit 01 of the previous stage and between the shift register unit 01 of the current stage and the shift register unit 01 of the next stage. The second output signal provides a gate drive signal for one of the scanning lines in the display apparatus. In addition, the first pull-down node PD1 and the second pull-down node PD2 maintain at the second potential because the sixth transistor M6A and the twelfth transistor M6B are still turned on. The first fixed voltage terminal LVGL outputs a first fixed voltage signal at the second potential to the first pull-down node PD1 via the sixth transistor M6A, and outputs a first fixed voltage signal at the second potential to the second pull-down node PD2 via the twelfth transistor M6B. The ninth transistor M12A, the tenth transistor M13A, the fifteenth transistor M12B and the sixteenth transistor M13B are still turned off, to avoid affecting the potential of the pull-up node PU, the potential of the first output terminal OUT1 and the potential of the second output terminal OUT2.

In a reset phase t3, the signals output from the first reset signal terminal RSE1, the second reset signal terminal RSE2 and the second control terminal VDDe are at the first potential, the signals output from the signal input terminal INPUT, the clock signal terminal CLK and the first control terminal VDDo are at the second potential, the first transistor M1 is turned off, and the second transistor M2, the third transistor M4 and the fourth transistor M15 are turned on. The first fixed voltage terminal LVGL outputs a first fixed voltage signal to the pull-up node PU via the second transistor M2 or the fourth transistor M15. In addition, the second fixed voltage terminal VGL outputs a second fixed voltage signal to the first output terminal OUT1 via the third transistor M4. It can be seen from FIG. 7 that the potential of the first fixed voltage signal is equal to the potential of the second fixed voltage signal, and both are a low potential VGL, such that the pull-up node PU and the first output terminal OUT1 are reset. In this case, the sixth transistor M6A, the seventh transistor M7A, the twelfth transistor M6B, the thirteenth transistor M7B, the first output transistor M3 and the second output transistor M11 are turned off. Moreover, the signal output from the second control terminal VDDe is at the first potential, such that the second control terminal VDDe outputs a second control signal at the first potential to the second pull-down node PD2 via the eleventh transistor M5B. Thus, the fourteenth transistor M8B, the fifteenth transistor M12B and the sixteenth transistor M13B are turned on. The first fixed voltage terminal LVGL outputs a first fixed voltage signal at the second potential to the pull-up node PU via the fourteenth transistor M8B, to further lower down the potential of the pull-up node PU. Furthermore, the first fixed voltage terminal LVGL outputs a first fixed voltage signal at the second potential to the second output terminal OUT2 via the fifteenth transistor M12B, to lower down the potential of the second output terminal OUT2. The first fixed voltage terminal LVGL outputs a first fixed voltage signal at the second potential to the first output terminal OUT1 via the sixteenth transistor M13B, to further lower down the potential of the first output terminal OUT1. That is, the pull-up node PU, the first output terminal OUT1 and the second output terminal OUT2 are reset in this phase.

To now, the process of outputting the gate drive signal by the shift register unit 01 is completed, and the shift register unit 01 only needs to keep outputting a low level signal continuously during subsequent operation of other shift register units 01. The subsequent process in which the shift register unit 01 keeps outputting the low level signal continuously is a holding phase t4 after the output phase t3.

In the holding phase t4, the input signal output from the signal input terminal INPUT, the first reset signal output from the first reset signal terminal RSE1 and the second reset signal output from the second reset signal terminal RSE2 maintain at the second potential. A first control signal output from the first control terminal VDDo and a second control signal output from the second control terminal VDDe are alternately at the first potential. Thus, the fifth transistor M5A and the eleventh transistor M5B are turned on alternately and the potential of the first pull-down node PD1 and the potential of the second pull-down node PD2 are alternately at the first potential. When the first pull-down node PD1 is at the first potential and the second pull-down node PD2 is at the second potential, the ninth transistor M12A and the tenth transistor M13A are turned on, and the fifteenth transistor M12B and the sixteenth transistor M13B are turned off. The first fixed voltage terminal LVGL outputs the first fixed voltage signal at the second potential to the second output terminal OUT2 via the ninth transistor M12A, and the second fixed voltage terminal VGL outputs the second fixed voltage signal at the second potential to the first output terminal OUT1 via the tenth transistor M13A. When the first pull-down node PD1 is at the second potential and the second pull-down node PD2 is at the first potential, the ninth transistor M12A and the tenth transistor M13A are turned off, and the fifteenth transistor M12B and the sixteenth transistor M13B are turned on. The first fixed voltage terminal LVGL outputs the first fixed voltage signal at the second potential to the second output terminal OUT2 via the fifteenth transistor M12B, and the second fixed voltage terminal VGL outputs the second fixed voltage signal at the second potential to the first output terminal OUT1 via the sixteenth transistor M13B.

Since the control signals output from the two control terminals VDDo and VDDe have the same frequency and opposite phases during the holding phase t4, the two control terminals VDDo and VDDe continuously output the signals at the second potential to the first output terminal OUT1 and the second output terminal OUT2, such that the first output terminal OUT1 and the second output terminal OUT2 maintain the second potential.

It should be noted that an example in which the transistors are N-type transistors and the first potential is a high potential relative to the second potential is used for description in the foregoing embodiments. Certainly, the transistors may also be P-type transistors, and when the transistors are P-type transistors, the connection relationship between the transistors remain unchanged, and the potential change at the various signal terminals are opposite to the potential change shown in FIG. 7 (that is, the phase difference is 180 degrees).

From the above circuit diagram and driving process of the shift register unit 01, it can be seen that the potential of the pull-up node PU rises to 2 times of VGH in the output phase t2. Therefore, in the embodiments of the present disclosure, in order to avoid the TFTs whose source or drain is connected to the pull-up node PU from heating or burning, among the plurality of TFTs whose source or drain is connected to the pull-up node PU, the target TFT unit in the target TFT is designed as the TFT unit including the floating electrode 15. That is, the target TFT unit is the TFT unit 1 in the above embodiments.

Referring to FIG. 6, the first electrode or the second electrode of each of the first transistor M1, the second transistor M2, the fourth transistor M15, the eighth transistor M8A and the fourteenth transistor M8B is connected to the pull-up node PU. That is, the first transistor M1, the second transistor M2, the fourth transistor M15, the eighth transistor M8A and the fourteenth transistor M8B are all target TFTs.

In the embodiments of the present disclosure, at least one of the first transistor M1, the second transistor M2, the fourth transistor M15, the eighth transistor M8A and the fourteenth transistor M8B includes the target TFT unit, that is, the TFT unit of the target structure. The TFT unit of the target structure is the TFT unit 1 in the above embodiments.

In some embodiments, the second transistor M2, the eighth transistor M8A and the fourteenth transistor M8B all include the target TFT unit. Further, both the first transistor M1 and the fourth transistor M15 include the target TFT unit.

Referring to FIG. 5 and FIG. 8, except the target TFT unit, other TFT units 2 in the plurality of TFTs each include a second gate 21, a second gate insulating layer 22, a second semiconductor layer 23, and a second source/drain electrode layer 24 that are sequentially arranged on the substrate. The second source/drain electrode layer 24 includes a second source 241 and a second drain 242 spaced apart from each other. Other TFT units 2 do not include the floating electrode 15.

In some embodiments, the length of the channel of the target TFT unit is twice the length of channels of the other TFT units. The channel of the target TFT unit is a part of the first semiconductor layer 13 which is overlapped with the first gate 11 and not overlapped with the floating electrode 15, the first source 141 and the first drain 142. The channel of each of the other TFT units is a part of the second semiconductor layer 23 which is overlapped with the second gate 21 and not overlapped with the second source 241 and the second drain 242. The length direction of the channel is parallel to the arrangement direction of the source and the drain of the transistor.

In the embodiments of the present disclosure, if the length of the floating electrode 15 in the target TFT unit in the first direction X (that is, the width of the floating electrode 15) is too large, a single target TFT unit occupies a larger plane area, which is not conducive to the current mainstream narrow-bezel products, while the minimum length depends mainly on the process capability. In some embodiments, the length of the floating electrode 15 in the first direction X is 3 μm or 3.5 μm. For example, in a product, for an ordinary TFT unit, the length of the source in the first direction X and the length of the drain in the first direction X are 3.5 μm and the length of the channel is 5 μm. The target TFT unit (for example, the first transistor M1, the second transistor M2, the fourth transistor M15, the eighth transistor M8A and the fourteenth transistor M8B) is of the target structure; and the length of the first source 141 in the first direction X, the length of the first drain 142 in the first direction X and the length of the floating electrode 15 in the first direction X are all 3 μm, but the length of the channel of the target TFT unit is 10 μm. In contrast, in another product, for an ordinary TFT unit, the length of the source in the first direction X and the length of the drain in the first direction X are 3 μm, and the length of the channel is 5 μm. The target TFT unit (for example, the first transistor M1, the second transistor M2, the fourth transistor M15, the eighth transistor M8A, and the fourteenth transistor M8B) is of the target structure; and the length of the first source 141 in the first direction X, the length of the first drain 142 in the first direction X, and the length of the floating electrode 15 in the first direction X are all 3 μm, but the length of the channel of the target TFT unit is 10 μm.

According to the characteristic principle of the TFT unit, the normalized current Ion of the current Ids between the source and the drain of the TFT unit satisfies formula: Ion=Ids/(W/L). Moreover, according to the foregoing formula (1), the current Ids between the source and the drain is positively correlated with the electron mobility μ, the unit-area capacitance Cox of the TFT unit and the width/length ratio (W/L) of the TFT unit, and can be simply expressed as

$$Ids ∝ μ * Cox * ( \frac{W}{L} ) ,$$

wherein ∝ represents the positive correlation. The electron mobility μ is a parameter related to the material and process of the semiconductor layer. Therefore, in the same manufacturing process, if the width/length ratio W/L remains unchanged, there are only process fluctuations and there is no big difference in the electron mobility μ.

The characteristics of some TFT units in the shift register unit 01 including the above 18T1C (that is, 18 TFT units and one storage capacitor C) are tested using laboratory equipment. Referring to FIG. 9, the normalized current Ion of the second transistor M2 and the eighth transistor M8A (the second transistor M2 and the eighth transistor M8A include the target TFT unit) is 8.0 μA. The normalized current Ion of the sixth transistor M6A is 8.9 μA, and the normalized current Ion of the second output transistor M11 is 8.5 μA. With reference to the above process fluctuation principle, it can be approximately considered that basically there is no big difference between the normalized current of the target TFT unit and the normalized current of other TFT units in actual design.

Moreover, referring to FIG. 9, there is only a small difference among the mobility of the second transistor M2, the mobility of the eighth transistor M8A, the mobility of the sixth transistor M6A and the mobility of the second output transistor M11. For example, the mobility of the second transistor M2 is 9.0 cm²/V·S, the mobility of the eighth transistor M8A is 10.0 cm²/V·S, the mobility of the sixth transistor M6A is 9.5 cm²/V·S, and the mobility of the second transistor M11 is 9.9 cm²/V·S. That is, by adding the floating electrode 15 to the TFT unit included in the TFT, the performance of the transistor is not greatly affected, and the performance requirements on the transistor can be met.

Because the floating electrode 15 is added to the target TFT unit, the plane area occupied by the TFT increases, which is not beneficial to the popular narrow bezel. However, because each TFT in the shift register unit 01 includes a plurality of TFT units connected in parallel, the shape is flexible, and the influence is limited. For example, the first transistor M1, the second transistor M2, the fourth transistor M15, the eighth transistor M8A and the fourteenth transistor M8B in a product all include the target TFT unit, i.e., all include the floating electrode 15, but the frame of the product is only 1.7 mm, which is better than 95% of the products in the factory.

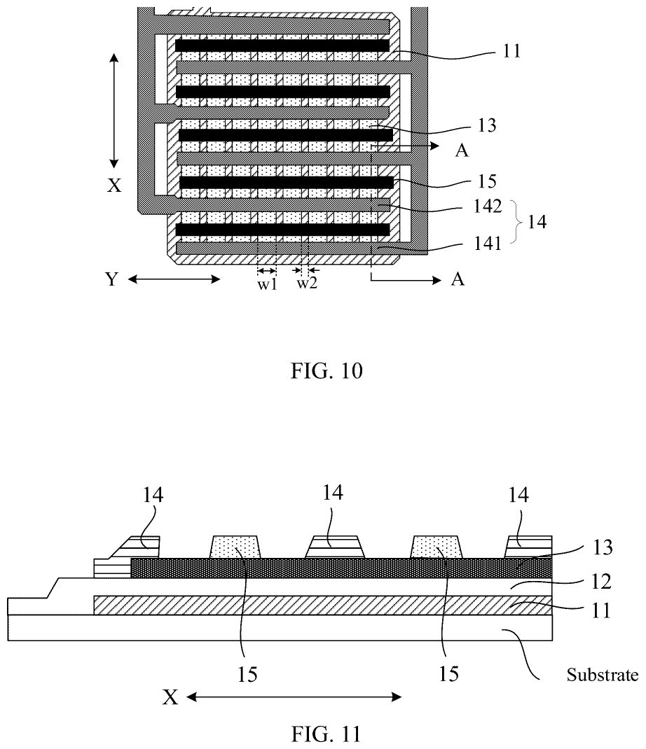

FIG. 10 is a partial schematic structural diagram of the shift register unit in FIG. 5. FIG. 11 is a cross-sectional view of FIG. 10 along a direction AA. Referring to FIG. 10 and FIG. 11, it can be seen that the semiconductor layer of the first transistor M1 includes a plurality of stripe patterns arranged in the second direction Y and extending in the first direction X.

In some embodiments, referring to FIG. 10, the length w1 of each stripe pattern in the second direction Y (that is, the width of the stripe pattern) ranges from 1.5 μm to 3.5 μm, for example, 2.5 μm. The distance w2 between two adjacent stripe patterns in the second direction Y ranges from 3 μm to 7 μm, for example, 5 μm.

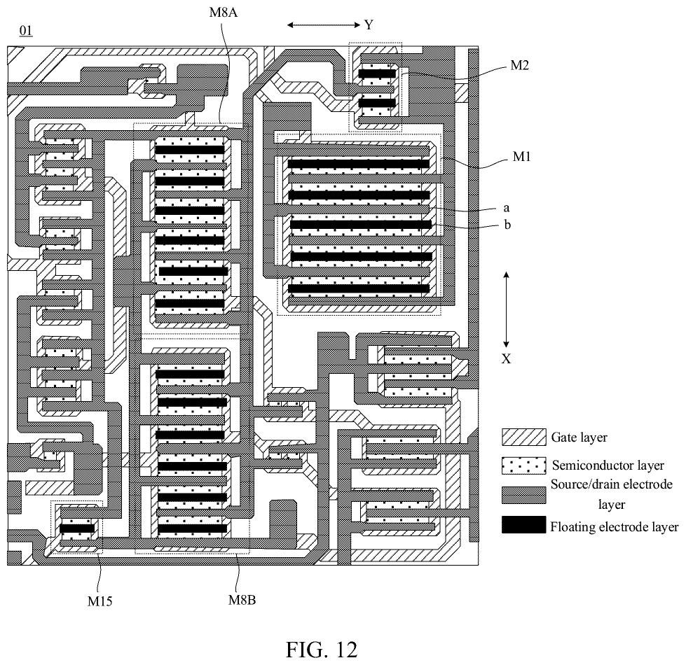

Certainly, referring to FIG. 12, the semiconductor layer of the first transistor may alternatively be an integral structure, and the structure of the semiconductor layer is not limited in the embodiments of the present disclosure.

In the embodiments of the present disclosure, the structure of the semiconductor layers 14 of the transistors other than the first transistor M1 in the shift register unit 01 is the same as or different from the structure of the semiconductor layer of the first transistor M1, which is not limited in the embodiments of the present disclosure.

Referring to FIG. 5, FIG. 11 and FIG. 12, at least one TFT includes a source/drain electrode branch a and a floating electrode branch b. The source/drain electrode branch a constitutes the source and drain of each TFT unit in the TFT, and the floating electrode branch b constitutes the floating electrode of each TFT unit in the TFT. A first number of the source/drain electrode branches in each TFT is greater than a second number of the floating electrode branches in the TFT, and a difference between the first number and the second number is greater than or equal to 1.

If the difference between the first number and the second number is equal to 1, it indicates that one floating electrode branch b is disposed between every two source/drain electrode branches a. If the difference between the first number and the second number is greater than 1, it indicates that there are two source/drain electrode branches a without the floating electrode branch b between them.

In addition, referring to FIG. 11, the first transistor M1 includes a plurality of TFT units connected in parallel. That is, the first transistor M1 is formed by connecting a plurality of TFT units in parallel, and the structure of each TFT unit is the structure of the TFT unit 1 provided in the above embodiments. Moreover, in order to save the layout space, two adjacent TFT units share one source/drain electrode branch, and the source/drain electrode branch is used as the source of one of the two TFT units and as the drain of the other TFT unit.

In summary, the embodiments of the present disclosure provide a shift register unit. In the shift register unit, the pull-up node has a higher voltage at the output phase due to the bootstrap effect of the storage capacitor. Therefore, among the plurality of TFTs in the shift register unit, the plurality of target TFTs whose source or drain is connected to the pull-up node are likely to heat or burn. For this, the TFT unit included in at least one target TFT in the plurality of target TFTs is designed as the target structure including the floating electrode, such that the floating electrode can have the function to dissipate heat for the at least one target TFT, thereby preventing the at least one target TFT from heating or even burning. In this way, the stability and reliability of the shift register unit is improved, and the display effect of the display apparatus is further improved.

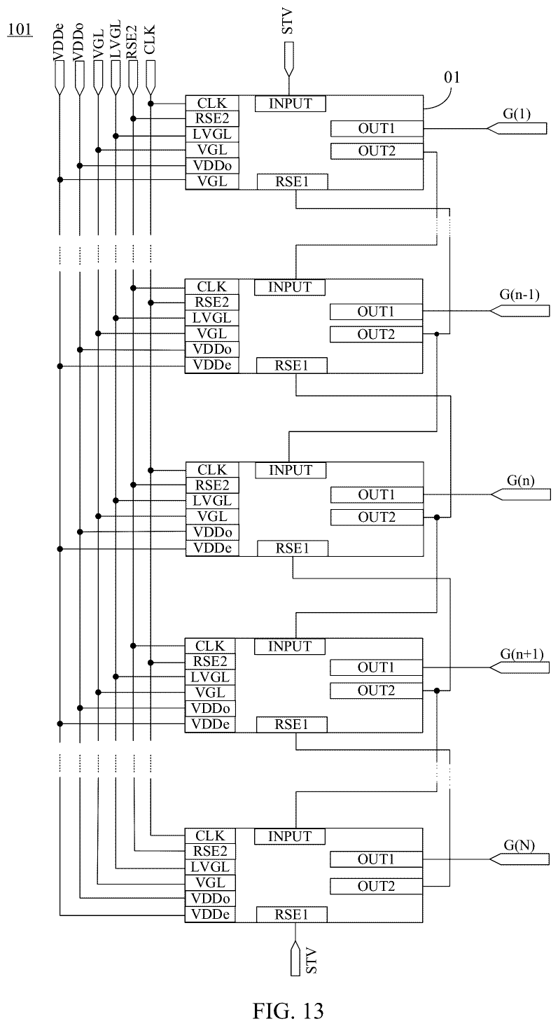

FIG. 13 is a schematic structural diagram of a gate drive circuit according to some embodiments of the present disclosure. Referring to FIG. 13, the gate drive circuit 00 includes at least two cascaded shift register units 01, and each shift register unit 01 is the shift register unit 01 as shown in FIG. 6.

As can be seen from FIG. 13, the signal input terminal INPUT of the shift register unit 01 of each stage is connected to the second output terminal OUT2 of the shift register unit 01 of the previous stage; the first reset signal terminal RST1 of the shift register unit 01 of each stage is connected to the second output terminal OUT2 of the shift register unit 01 of the next stage; and the first output terminal OUT1 of the shift register unit 01 of each stage is connected to a scanning line. For example, the signal input terminal INPUT of the shift register unit 01 of an n^{th} stage is connected to the second output terminal OUT2 (n−1) of the shift register unit 01 of an (n−1)^{th} stage, the first reset signal terminal RST1 of the shift register unit 01 of the n^{th} stage is connected to the output terminal OUT2 (n+1) of the shift register unit 01 of an (n+1)^{th} stage, and the first output terminal of the shift register unit 01 of the n^{th} stage is connected to an n^{th} scanning line G(n). It can also be seen from FIG. 12 that in the gate drive circuit 00, the signal input terminal INPUT of the shift register unit 01 of the first stage and the first reset signal terminal RST1 of the shift register unit 01 of the last stage are connected to a frame start signal terminal STV.

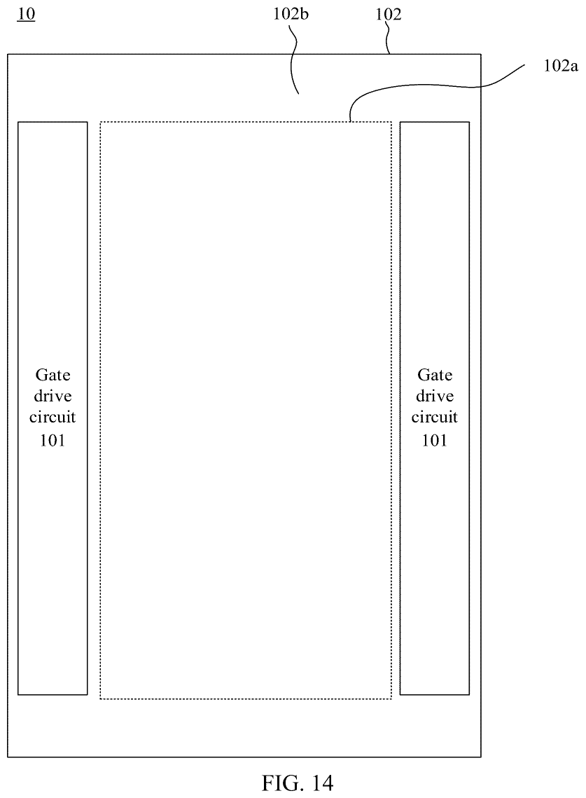

FIG. 14 is a schematic structural diagram of a display panel according to some embodiments of the present disclosure. Referring to FIG. 14, the display panel 10 includes a substrate 102 and the gate drive circuit 101 according to the above embodiments. The gate drive circuit 101 is disposed on the substrate 102.

In some embodiments, the substrate 102 includes a display region 102a and a peripheral region 102b surrounding the display region 102a, and the gate drive circuit 00 is disposed in the peripheral region 102b of the substrate 102. For example, in FIG. 13, the gate drive circuit 00 is disposed in the parts, at the left and right sides of the display region 102a, of the peripheral region 102b.

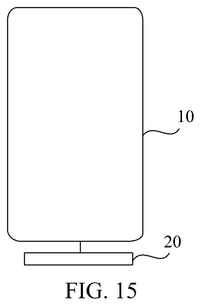

FIG. 15 is a schematic structural diagram of a display apparatus according to some embodiments of the present disclosure. Referring to FIG. 15, the display apparatus includes a power supply assembly 20 and the display panel 10 provided in the above embodiments. The power supply assembly 20 is configured to supply power to the display panel 10.

In some embodiments, the display apparatus is any product or component with a display function, such as a liquid crystal display apparatus, an organic light-emitting diode (OLED) display apparatus, electronic paper, a low temperature poly-silicon (LTPS) display apparatus, a mobile phone, a tablet computer, a TV, a display, a notebook computer, a digital photo frame, or a navigator.

The transistors adopted in the embodiments of the present disclosure are mainly switching transistors according to their functions in the circuit. Because the source and the drain of the switching transistor are symmetrical, the source and the drain are interchangeable. In the embodiments of the present disclosure, the source is referred to as the first electrode and the drain is referred to as the second electrode. According to the structure in the accompanying drawings, a middle terminal of the transistor is a gate, a signal input terminal is the source, and a signal output terminal is the drain. In addition, the switching transistor in the embodiments of the present disclosure may an N-type switching transistor or a P-type switching transistor. The N-type switching transistor is turned on when the gate is at a high level and turned off when the gate is at a low level. The P-type switching transistor is turned on when the gate is at the low level and turned off when the gate is at the high level. In addition, a plurality of signals in the embodiments of the present disclosure each have a first potential and a second potential. The first potential and the second potential only represent that the potential of the signal has two state variables, but do not represent that the first potential or the second potential in this specification has a specific value. The embodiments of the present disclosure are described by taking an example in which the first potential is a high potential relative to the second potential.

It should be understood that although terms such as first, second, and third are used to describe various elements, components, regions, layers and/or portions, these elements, components, regions, layers and/or portions should not be limited by these terms. These terms are only used to distinguish one element, component, region, layer or portion from another element, component, region, layer or portion. Therefore, the first element, component, region, layer or portion discussed above may also be referred to as a second element, part, region, layer, or portion without deviating from the teaching of the present disclosure.

For ease of description, spatial relative terms such as “row”, “column”, “under”, “on”, “left”, “right” are used to describe the relationship of one element or feature shown in the figure with respect to another element or feature. It should be understood that in addition to the orientations shown in the figure, the spatial relative terms further include different orientations of used and operating devices. For example, if the device in the figure is turned upside down, elements described as being “under” other elements or features will be located “on” the other elements or features. Therefore, the exemplary term “under” can encompass being on and under. The component may also be positioned in other different ways (rotated by 90 degrees or in other orientations), and the spatial relative description should be explained accordingly. It can also be understood that, when a layer is referred to as being “between” two layers, it may be the only layer between the two layers, or there may be one or more intermediate layers.

The terms used herein are only used to describe specific embodiments and are not intended to limit the present disclosure. In the present disclosure, the singular forms of “a”, “an” and “the” may also include the plural forms, unless clearly specified otherwise. It should also be understood that the terms “include” and/or “comprise” are used herein to indicate the existence of the stated features, integers, steps, operations, elements and/or parts, without exclusion or addition of one or more other features, integers, steps, operations, elements, parts and/or groups. The term “and/or” used herein includes any and all combinations of one or more of the associated listed items. Moreover, the specific features, structures, materials or characteristics described in the preset disclosure may be combined in a suitable manner in any one or more embodiments or examples. In addition, those skilled in the art may combine different embodiments or examples described in this specification and characteristics of the different embodiments or examples without mutual contradiction.

Unless defined otherwise, all terms (including technical and scientific terms) used herein have the same meanings as commonly understood by one of ordinary skill in the art to which the present disclosure belongs. It should be also understood that terms such as those defined in commonly used dictionaries should be interpreted as having the meaning consistent with the meaning in the relevant field and/or in the context of this specification, and may not be interpreted in an idealized or overly formal sense unless expressly defined herein.

The foregoing descriptions are merely optional embodiments of the present disclosure and are not intended to limit the present disclosure. Any modifications, equivalent replacements, and improvements within the spirit and principles of the present disclosure shall be included within the protection scope of the present disclosure.

1. A thin film transistor (TFT) unit, comprising:
a first gate, a first gate insulating layer, a first semiconductor layer and a first source/drain electrode layer that are sequentially arranged on a substrate, wherein the first source/drain electrode layer comprises a first source and a first drain that are spaced apart from each other along a first direction; and
a floating electrode disposed on a side of the first semiconductor layer away from the first gate insulating layer, wherein in the first direction, an orthographic projection of the floating electrode on the substrate falls between an orthographic projection of the first source on the substrate and an orthographic projection of the first drain on the substrate;
wherein the orthographic projection of the floating electrode on the substrate is at least partially overlapped with an orthographic projection of the first semiconductor layer on the substrate; the orthographic projection of the floating electrode on the substrate, the orthographic projection of the first source on the substrate and the orthographic projection of the first drain on the substrate each are at least partially overlapped with an orthographic projection of the first gate on the substrate; any two of the floating electrode, the first source and the first drain are at least partially overlapped in a second direction, and the second direction is perpendicular to the first direction.

2. The TFT unit according to claim 1, wherein the floating electrode, the first source, and the first drain are disposed on a same layer.

3. The TFT unit according to claim 1, wherein a material of the floating electrode comprises metal.

4. The TFT unit according to claim 1, wherein a length of the floating electrode in the first direction, a length of the first source in the first direction and a length of the first drain in the first direction are equal.

5. The TFT unit according to claim 1, wherein the first source, the floating electrode and the first drain are equally spaced apart from each other in the first direction.

6. A method for manufacturing a thin film transistor (TFT) unit, comprising:
sequentially forming a first gate, a first gate insulating layer, a first semiconductor layer and a first source/drain electrode layer on a substrate, wherein the first source/drain electrode layer comprises a first source and a first drain that are spaced apart from each other along a first direction; and
forming a floating electrode on a side of the first semiconductor layer away from the substrate, wherein in the first direction, an orthographic projection of the floating electrode on the substrate falls between an orthographic projection of the first source on the substrate and an orthographic projection of the first drain on the substrate;
wherein the orthographic projection of the floating electrode on the substrate is at least partially overlapped with an orthographic projection of the first semiconductor layer on the substrate; the orthographic projection of the floating electrode on the substrate, the orthographic projection of the first source on the substrate and the orthographic projection of the first drain on the substrate each are at least partially overlapped with an orthographic projection of the first gate on the substrate; any two of the floating electrode, the first source and the first drain are at least partially overlapped in a second direction, and the second direction is perpendicular to the first direction.

7. The method according to claim 6, wherein forming the first source/drain electrode layer and the floating electrode comprises:
forming a source/drain electrode film on the side of the first semiconductor layer away from the substrate; and
patterning the source/drain electrode film to obtain the first source, the first drain and the floating electrode.

8. A shift register unit, wherein the shift register unit comprises a plurality of thin film transistors (TFTs), each of the thin film transistors (TFTs) comprises at least one TFT unit, the plurality of TFTs comprise a plurality of target TFTs, a source or drain of each of the target TFTs is connected to a pull-up node in the shift register unit, at least one of the plurality of target TFTs comprises a target TFT unit, and the target TFT unit is of a target structure, wherein the target structure comprises:
a first gate, a first gate insulating layer, a first semiconductor layer and a first source/drain electrode layer that are sequentially arranged on a substrate, wherein the first source/drain electrode layer comprises a first source and a first drain that are spaced apart from each other along a first direction; and
a floating electrode disposed on a side of the first semiconductor layer away from the first gate insulating layer, wherein in the first direction, an orthographic projection of the floating electrode on the substrate falls between an orthographic projection of the first source on the substrate and an orthographic projection of the first drain on the substrate;
wherein the orthographic projection of the floating electrode on the substrate is at least partially overlapped with an orthographic projection of the first semiconductor layer on the substrate; the orthographic projection of the floating electrode on the substrate, the orthographic projection of the first source on the substrate and the orthographic projection of the first drain on the substrate each are at least partially overlapped with an orthographic projection of the first gate on the substrate; any two of the floating electrode, the first source and the first drain are at least partially overlapped in a second direction, and the second direction is perpendicular to the first direction.

9. The shift register unit according to claim 8, wherein each of the plurality of target TFT comprises the target TFT unit.

10. The shift register unit according to claim 8, wherein the shift register unit comprises an input circuit, a first reset circuit, an output circuit, a second reset circuit, a first pull control circuit, a first pull circuit, a second pull control circuit, a second pull circuit, and a storage capacitor; wherein
the input circuit comprises a first transistor, wherein a gate and a first electrode of the first transistor are connected to a signal input terminal, and a second electrode of the first transistor is connected to the pull-up node;
the first reset circuit comprises a second transistor and a third transistor, wherein a gate of the second transistor is connected to a first reset signal terminal, a first electrode of the second transistor is connected to the pull-up node, and a second electrode of the second transistor is connected to a first fixed voltage terminal; and a gate of the third transistor is connected to the first reset signal terminal, a first electrode of the third transistor is connected to a first output terminal, and a second electrode of the third transistor is connected to a second fixed voltage terminal;
the output circuit comprises a first output transistor and a second output transistor, wherein a gate of the first output transistor is connected to the pull-up node, a first electrode of the first output transistor is connected to a clock signal terminal, and a second electrode of the first output transistor is connected to the first output terminal; and a gate of the second output transistor is connected to the pull-up node, a first electrode of the second output transistor is connected to the clock signal terminal, and a second electrode of the second output transistor is connected to a second output terminal;
the second reset circuit comprises a fourth transistor, wherein a gate of the fourth transistor is connected to a second reset signal terminal, a first electrode of the fourth transistor is connected to the pull-up node, and a second electrode of the fourth transistor is connected to the first fixed voltage terminal;
the first pull control circuit comprises a fifth transistor, a sixth transistor and a seventh transistor, wherein a gate and a first electrode of the fifth transistor are connected to a first control terminal, and a second electrode of the fifth transistor is connected to a first pull-down node, a gate of the sixth transistor is connected to the pull-up node, a first electrode of the sixth transistor is connected to the first pull-down node, and a second electrode of the sixth transistor is connected to the first fixed voltage terminal; and a gate of the seventh transistor is connected to the signal input terminal, a first electrode of the seventh transistor is connected to the first pull-down node, and a second electrode of the seventh transistor is connected to the first fixed voltage terminal;
the first pull circuit comprises an eighth transistor, a ninth transistor and a tenth transistor, wherein a gate of the eighth transistor is connected to the first pull-down node, a first electrode of the eighth transistor is connected to the pull-up node, and a second electrode of the eighth transistor is connected to the first fixed voltage terminal; a gate of the ninth transistor is connected to the first pull-down node, a first electrode of the ninth transistor is connected to the second output terminal, and a second electrode of the ninth transistor is connected to the first fixed voltage terminal; and a gate of the tenth transistor is connected to the first pull-down node, a first electrode of the tenth transistor is connected to the first output terminal, and a second electrode of the tenth transistor is connected to the second fixed voltage terminal;
the second pull control circuit comprises an eleventh transistor, a twelfth transistor and a thirteenth transistor, wherein a gate and a first electrode of the eleventh transistor are connected to a second control terminal, and a second electrode of the eleventh transistor is connected to a second pull-down node; a gate of the twelfth transistor is connected to the pull-up node, a first electrode of the twelfth transistor is connected to the second pull-down node, and a second electrode of the twelfth transistor is connected to the first fixed voltage terminal; and a gate of the thirteenth transistor is connected to the signal input terminal, a first electrode of the thirteenth transistor is connected to the second pull-down node, and a second electrode of the thirteenth transistor is connected to the first fixed voltage terminal;
the second pull circuit comprises a fourteenth transistor, a fifteenth transistor and a sixteenth transistor, wherein a gate of the fourteenth transistor is connected to the second pull-down node, a first electrode of the fourteenth transistor is connected to the pull-up node, and a second electrode of the fourteenth transistor is connected to the first fixed voltage terminal; a gate of the fifteenth transistor is connected to the second pull-down node, a first electrode of the fifteenth transistor is connected to the second output terminal, and a second electrode of the fifteenth transistor is connected to the first fixed voltage terminal; and a gate of the sixteenth transistor is connected to the second pull-down node, a first electrode of the sixteenth transistor is connected to the first output terminal, and a second electrode of the sixteenth transistor is connected to the second fixed voltage terminal; and
a first electrode of the storage capacitor is connected to the pull-up node, and a second electrode of the storage capacitor is connected to the first output terminal;
wherein one of the first electrode and second electrode of each transistor is the source and the other one is the drain.

11. The shift register unit according to claim 10, wherein at least one of the first transistor, the second transistor, the fourth transistor, the eighth transistor and the fourteenth transistor comprises the target TFT unit.

12. The shift register unit according to claim 11, wherein each of the second transistor, the eighth transistor and the fourteenth transistor comprises the target TFT unit.

13. The shift register unit according to claim 12, wherein both first transistor and the fourth transistor comprise the target TFT unit.

14. The shift register unit according to claim 8, wherein except the target TFT units, other TFT units in the plurality of TFTs each comprise a second gate, a second gate insulating layer, a second semiconductor layer and a second source/drain electrode layer that are sequentially arranged on the substrate, wherein the second source/drain electrode layer comprises a second source and a second drain that are spaced apart from each other, and the other TFT units do not comprise the floating electrode.

15. The shift register unit according to claim 14, wherein a length of a channel of the target TFT unit is twice a length of each of channels of the other TFT units; wherein
the channel of the target TFT unit is a part of the first semiconductor layer which is overlapped with the first gate and is not overlapped with the floating electrode, the first source and the first drain, the channel of each of the other TFT units is a part of the second semiconductor layer which is overlapped with the second gate and is not overlapped with the second source and the second drain, and a length direction of the channel is parallel to an arrangement direction of the second source and the second drain of the transistor.

16. The shift register unit according to claim 8, wherein each of the TFTs is an N-type transistor.

17. The shift register unit according to claim 8, wherein at least one of the plurality of TFTs comprises a source/drain electrode branch and a floating electrode branch; wherein
the source/drain electrode branch constitutes a source and a drain of each TFT unit in the TFT, and the floating electrode branch constitutes a floating electrode of each TFT unit in the TFT; and
a first number of the source/drain electrode branches in the TFT is greater than a second number of the floating electrode branches in the TFT, and a difference between the first number and the second number is greater than or equal to 1.

18. A gate drive circuit, wherein the gate drive circuit comprises:
at least two cascaded shift register units according to claim 8.

19. A display panel, wherein the display panel comprises a substrate and the gate drive circuit according to claim 18, wherein the gate drive circuit is disposed on the substrate.

20. A display apparatus, comprising a power supply assembly and the display panel according to claim 19; wherein
the power supply assembly is configured to supply power to the display panel.
